(19) United States
(12) Patent Application Publication
(10) Pub. No.: US 2014/0159042 A1
(43) Pub. Date: Jun. 12, 2014

(54) TOP DOWN ALUMINUM INDUCED CRYSTALLIZATION FOR HIGH EFFICIENCY PHOTOVOLTAICS

(71) Applicants: Douglas Arthur Hutchings, Elkins, AR (US); Seth Daniel Shumate, Fayetteville, AR (US); Hameed Naseem, Fayetteville, AR (US)

(72) Inventors: Douglas Arthur Hutchings, Elkins, AR (US); Seth Daniel Shumate, Fayetteville, AR (US); Hameed Naseem, Fayetteville, AR (US)

(73) Assignees: SILICON SOLAR SOLUTIONS, LLC, Fayetteville, AR (US); BOARD OF TRUSTEES OF THE UNIVERSITY OF ARKANSAS, Little Rock, AR (US)

(21) Appl. No.: 14/002,875

(22) PCT Filed: Mar. 2, 2012
(86) PCT No.: PCT/US2012/027505

§ 371 Date: Feb. 18, 2014

Related U.S. Application Data
(60) Provisional application No. 61/449,050, filed on Mar. 3, 2011.

(30) Foreign Application Priority Data
Jun. 8, 2011 (IB) PCT US2011/039574

(51) Int. Cl. H01L 21/02; H01L 29/04

(52) U.S. Cl. CPC H01L 21/02669; H01L 21/02595; H01L 29/04; H01L 21/02529; H01L 21/02532
USPC 257/52; 438/486; 438/483

(57) ABSTRACT

Certain aspects of the present disclosure are directed to a method that includes: depositing, in a deposition environment, an amorphous semiconductor material on a substrate to form a semiconductor film on the substrate; filling, in the depositing process, the deposition environment with a first precursor material such that the semiconductor film formed on the substrate includes a first layer having a first material characteristic; filling, in the depositing process, the deposition environment with a crystallization-stop precursor material such that the silicon film includes a crystallization-stop layer having a crystallization characteristic different from a crystallization characteristic of the first layer; depositing a metal film on the semiconductor film; and annealing the semiconductor film and the metal film at an predetermined annealing temperature for a predetermined period of time such that the first layer is at least partially crystallized and the crystallization-stop layer is at least partially amorphous.

### CROSS-REFERENCE TO RELATED APPLICATIONS

This PCT application claims the benefit, pursuant to 35 U.S.C. §119(e), of U.S. Provisional Application No. 61/449,050, filed on Mar. 3, 2011 and entitled “DEVELOPMENT OF TOP DOWN ALUMINUM INDUCED CRYSTALLIZATION FOR HIGH EFFICIENCY PHOTOVOLTAICS.” This application is a Continuation-In-Part of PCT International Application No. PCT/US2011/039574, filed on Jun. 8, 2011 and entitled “CRYSTALLIZATION OF MULTI-LAYERED AMORPHOUS FILMS,” which claims the benefit, pursuant to 35 U.S.C. §119(e), of U.S. Provisional Patent Application Ser. No. 61/352,681, filed on Jun. 8, 2010 and entitled “Method of Metal Induced Crystallization of Amorphous Silicon and Method of Doping.” The disclosures of the above applications are incorporated herein by reference in their entireties.

Some references, which may include patents, patent applications and various publications, are cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference

### FIELD

The present disclosure generally relates to methods and apparatus for forming a polycrystalline film.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Energy is the most pressing issue of our time. Solar energy is a promising alternative energy source to traditional energy sources but adoption is hindered by the high upfront costs and delayed return-on-investment. Of all the materials being explored, silicon appears the most promising due to its availability, accessibility and lack of toxicity concerns. Solar energy currently represents a minute fraction of world's energy needs and expansion to a meaningful contribution requires an abundant material such as silicon. Silicon based devices likely will remain dominant through the foreseeable future.

The baseline cost of silicon based photovoltaic devices has been decreasing at about 6% annually. This trend has been consistent since the 1980s and the market demand has increased exponentially, typical of highly elastic markets. The tipping point for the solar market occurs when the installed system cost reaches “grid parity.” This is defined as the point in which solar energy becomes cost equivalent to traditional fuel sources, and is commonly referenced as an installed cost of $3 per peak watt ($/Wp). Current installations in some local communities are being performed at just over $5/Wp with the module representing almost $2.50/Wp or 50% of the system cost. A huge commercial opportunity exists for technologies that bring costs closer to grid parity by reducing module cost, and especially for the technology that brings the cost below grid parity.

Thin film silicon solar cells contain layers of deposited silicon and are typically less than 10 μm in thickness. The crystallinity of these silicon layers ranges from fully amorphous (a-Si:H) to a mixture of amorphous and crystalline (micro/nanocrystalline silicon) to fully crystallized polysilicon.

Several techniques exist for crystallization and are shown in Table 1 below. Solid Phase Crystallization (SPC) results in larger grain size, and requires 24 hours of annealing at above 550° C. in order to achieve full crystallization. Laser recrystallization and LPCVD suffer from small grain sizes that are detrimental to photovoltaic devices, either for polycrystalline emitter solar cells or thin film devices. Grain boundaries are riddled with defects, acting as carrier recombination killing fields. Typically larger grains mean fewer grain boundaries per unit area, enhancing carrier lifetime and conductivity.

TABLE 1

| | SPC | | Laser | LPCVD | |
|---|---|---|---|---|---|
| Temperature | 600-1000° | C. | 1415° C. at | 600° | C. |
| | | | Surface | | |
| Grain Size | 0.1-5 | μm | 30-300 nm | 30-100 | nm |

These methods generally suffer from high temperatures which limit substrate choice. These temperatures are also high enough to drive out atomic hydrogen which passivates defects. Thus, the film silicon photovoltaic devices produced may require re-hydrogenating the films. It is found that open circuit voltage increases of 200 mV for thin film polycrystalline solar cells after hydrogenation. This requires additional processing which again limits the viability of manufacturing efforts.

Therefore, a heretofore unaddressed need exists in the art to address the aforementioned deficiencies and inadequacies.

### SUMMARY

Certain aspects of the present disclosure are directed to a method. In certain embodiments, the method includes: (a) depositing, in a deposition environment, an amorphous semiconductor material on a substrate to form a semiconductor film on the substrate; (b) filling, in the depositing process (a), the deposition environment with a first precursor material such that the semiconductor film formed on the substrate includes a first layer having a first material characteristic; (c) filling, in the depositing process (a), the deposition environment with a crystallization-stop precursor material such that the silicon film includes a crystallization-stop layer having a crystallization characteristic different from a crystallization characteristic of the first layer; (d) depositing a metal film on the semiconductor film; and (e) annealing the semiconductor film and the metal film at an predetermined annealing temperature for a predetermined period of time such that the first layer is at least partially crystallized and the crystallization-stop layer is at least partially amorphous.

In certain embodiments, the method further includes (f) filling, in the depositing process (a), the deposition environment with a second precursor material such that the silicon film formed on the substrate includes a second layer having a second material characteristic different from the first material characteristic. The crystallization characteristic of the crystallization-stop layer is different from a crystallization characteristic of the second layer. The semiconductor film is annealed such that the second layer is at least partially crystallized.

In certain embodiments, the method further includes (g) filling, in the depositing process (a), the deposition environment with a third precursor material such that the semiconductor film formed on the substrate includes a third layer having a third material characteristic. The semiconductor film is annealed such that the third layer is at least partially crystallized.

In certain embodiments, in the method, (g) is executed subsequent to (f), and (f) is executed subsequent to (b). In certain embodiments, in the method, (c) is executed prior to (b). In certain embodiments, in the method, (c) is executed such that the crystallization-stop layer is in contact with the substrate.

In certain embodiments, the amorphous semiconductor material is a hydrogenated amorphous silicon material. In certain embodiments, the first, second, third, and crystallization-stop precursor materials each are in gaseous forms. In certain embodiments, the first, second, and third layers are entirely crystallized, and the crystallization-stop layer is entirely amorphous.

In certain embodiments, the first precursor material is phosphine and the first layer contains an n+ hydrogenated amorphous silicon material. In certain embodiments, the second precursor material is silane and the second layer contains a hydrogenated amorphous silicon material. In certain embodiments, the third precursor material is diborane and the third layer contains a p+ hydrogenated amorphous silicon material.

In certain embodiments, the crystallization characteristic includes a crystallization temperature. In certain embodiments, the crystallization-stop precursor material is methane, and the crystallization-stop layer contains amorphous silicon carbide. In certain embodiments, the crystallization-stop layer has a thickness less than about 1 μm. In certain embodiments, the crystallization-stop layer has a thickness less than about 20 nm.

In certain embodiments, the annealing process is executed in an atomic hydrogen environment. In certain embodiments, the annealing temperature is above or equal to a first temperature at which the first, second, and third layers start crystallization in the annealing process and is below a second temperature at which the crystallization-stop layer starts crystallization in the annealing process. In certain embodiments, the annealing temperature is within a range from about 100° C. to about 1000° C.

In certain embodiments, the method includes forming a layer of amorphous silicon carbide having a thickness less than 1 μm. In certain embodiments, the metal film is an aluminum film. In certain embodiments, the substrate is a glass substrate.

In certain embodiments, the silicon film is formed to have a thickness within a range from about 0.1 μm to about 40 μm. In certain embodiments, the silicon film is formed by sputtering or chemical vapor deposition. In certain embodiments, the silicon film is formed by plasma-enhanced chemical vapor deposition at a pressure in a range from about 10⁻⁴ torr to about 10⁻⁶ torr. In certain embodiments, the aluminum layer is formed to have a thickness in a range from about 5 nm to about 300 nm. In certain embodiments, the aluminum layer is formed by sputtering or thermal evaporation. In certain embodiments, the aluminum layer is formed by sputtering at a pressure of about 10⁻⁸ torr. In certain embodiments, the predetermined period of time is within a range from about 15 minutes to about 20 hours.

In certain embodiments, the method includes at least one of: controlling rigidity of the substrate; controlling residual stress from the silicon film; controlling residual stress from the aluminum film; controlling coefficient of thermal expansion mismatch between the aluminum film, the silicon film, and the substrate; and controlling micro-structural changes the silicon film including crystallization kinetics.

In certain embodiments, the method includes at least one of: controlling a deposition temperature; controlling a deposition pressure; controlling a deposition precursor gases; controlling the annealing temperature; and controlling crystallization kinetics of the silicon film.

In certain embodiments, the method includes at least one of: controlling an annealing temperature profile; controlling an annealing environment; and controlling an annealing type.

Certain aspects of the present disclosure are directed to polycrystalline silicon film structure formed by the above method.

Certain aspects of the present disclosure are directed to a semiconductor film structure usable in a solar cell, including: a substrate; a semiconductor film formed on the substrate. The semiconductor film is a layer structure having a first layer having a first material characteristic and being at least partially crystallized, a crystallization-stop layer formed between the substrate and the first layer and being at least partially amorphous; and a metal film formed on the semiconductor film. In certain embodiments, in the semiconductor film structure, the semiconductor film further includes a second layer having a second material characteristic different from the first material characteristic and formed above the first layer, the second layer being at least partially crystallized. In certain embodiments, in the semiconductor film structure, the semiconductor film further includes a third layer having a third material characteristic different from the first and second material characteristics and formed above the second layer such that the second layer is positioned between the first and third layers.

In certain embodiments, in the semiconductor film structure, the semiconductor film is a silicon film. In certain embodiments, in the semiconductor film structure, the first layer contains an n+ polycrystalline silicon material. In certain embodiments, in the semiconductor film structure, the second layer contains a p type polycrystalline silicon material. In certain embodiments, in the semiconductor film, the third layer contains a p+ polycrystalline silicon material. In certain embodiments, in the semiconductor film structure, the crystallization-stop layer contains amorphous silicon carbide.

Certain aspects of the present disclosure are directed to a layered structure usable in a solar cell, including a silicon film having a first polycrystalline silicon layer having a first material characteristic; a second polycrystalline silicon layer having a second material characteristic and formed on the first layer; a third polycrystalline silicon layer having a third material characteristic formed on the second layer such that the second layer is positioned between the first and third layers, the first, second, and third material characteristics being different from each other; and a crystallization-stop layer formed in the silicon film and having a crystallization characteristic different from crystallization characteristics of the first, second and third layers. The first, second and third layers are at least partially crystallized and the crystallization-stop layer is at least partially amorphous.

In certain embodiments, in the layered structure, the first layer contains an n+ polycrystalline silicon material. In certain embodiments, in the layered structure, the second layer contains a p type polycrystalline silicon material. In certain embodiments, in the layered structure, the third layer contains a p+ polycrystalline silicon material. In certain embodiments, in the layered structure, the crystallization-stop layer contains amorphous silicon carbide.

Further areas of applicability of the present disclosure will become apparent from the detailed description provided hereinafter. It should be understood that the detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 schematically shows a cross-sectional side view of a polycrystalline film structure, according to certain embodiments of the present disclosure;

FIG. 2 is a cross-sectional view schematically illustrating three phases of metal-induced crystallization (MIC) for producing a doped polycrystalline film, according to certain embodiments of the present disclosure;

FIG. 3 schematically shows a cross-section of deposited layers and corresponding deposition methods and precursor gas environments for forming a polycrystalline film structure, according to certain embodiments of the present disclosure;

FIG. 4 schematically shows an annealing process, according to certain embodiments of the present disclosure; and

FIG. 5 is a stress-temperature crystallization phase diagram.

### DETAILED DESCRIPTION

The present disclosure will now be described more fully hereinafter with reference to the accompanying drawings, in which exemplary embodiments of the disclosure are shown. This disclosure may, however, be embodied in many different forms and should not be construed as limited to the embodiments set forth herein. Rather, these embodiments are provided so that this disclosure will be thorough and complete, and will fully convey the scope of the disclosure to those skilled in the art. Like reference numerals refer to like elements throughout.

The terms used in this specification generally have their ordinary meanings in the art, within the context of the disclosure, and in the specific context where each term is used. Certain terms that are used to describe the disclosure are discussed below, or elsewhere in the specification, to provide additional guidance to the practitioner regarding the description of the disclosure. For convenience, certain terms may be highlighted, for example using italics and/or quotation marks. The use of highlighting has no influence on the scope and meaning of a term; the scope and meaning of a term is the same, in the same context, whether or not it is highlighted. It will be appreciated that same thing can be said in more than one way. Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification including examples of any terms discussed herein is illustrative only, and in no way limits the scope and meaning of the disclosure or of any exemplified term. Likewise, the disclosure is not limited to various embodiments given in this specification.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present disclosure.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, the terms “comprising,” “including,” “carrying,” “having,” “containing,” “involving,” and the like are to be understood to be open-ended, i.e., to mean including but not limited to.

Certain aspects of the present disclosure are directed to thin-film silicon products that offer an excellent compromise between performance and required surface area in addition to having the scalability necessary to impact the world's energy demands. Certain embodiments of the present disclosure can enable current amorphous silicon solar cell manufacturers to improve their offerings with very little added cost.

Metal induced crystallization (MIC) is the process in which amorphous silicon is crystallized at temperatures below the solid phase crystallization temperature due to contact with one of several metals. The most useful and commonly studied metal has been aluminum. In certain circumstances, a layer exchange between aluminum and amorphous silicon occurs and the amorphous silicon layer becomes crystallized.

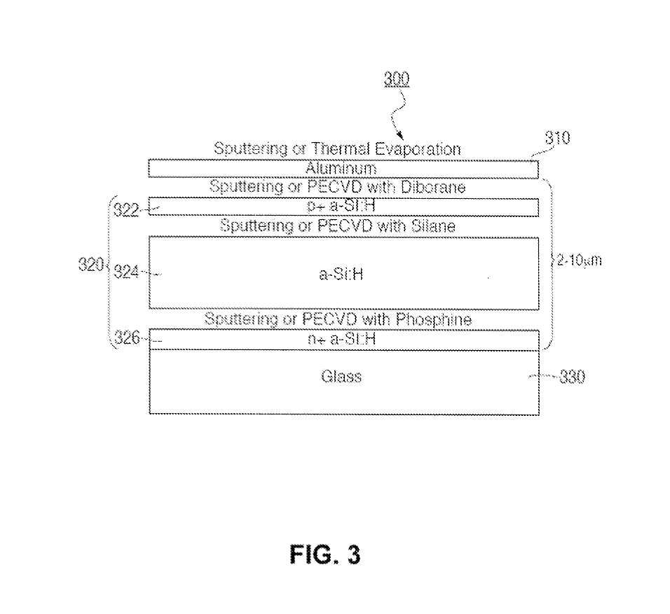

Top down aluminum induced crystallization (TAIC) of hydrogenated amorphous silicon (a-Si:H) is a novel variant of MIC. In TAIC, as shown in FIG. 3, a sub-micron layer of aluminum 310 deposited on top of a layer of amorphous silicon 320 is heated to catalyze the diffusion of aluminum and the crystallization of the amorphous layer without layer exchange. At the same time, aluminum is incorporated as an electrically active p-type acceptor impurity.

In certain embodiments, the crystallization of the amorphous silicon 320 can be controlled. The amorphous silicon 320 can be doped with little to no crystallization, which represents one extreme of the TAIC spectrum. The other extreme occurs when some silicon diffuses into the aluminum layer 310 creating a textured surface with features on the order of the wavelength of visible light; this represents a partial layer exchange.

TAIC has several key advantages over other methods of crystallizing amorphous silicon that make it amenable to large scale manufacturing and high quality devices. TAIC has created grains up to 150 μm in diameter (compared to 5 μm for SPC). TAIC has the substantial advantages over competing methods. Unlike other a-Si:H based devices, TAIC does not require high vacuum deposition (10⁻² Torr for TAIC vs. 10⁻⁸ Torr for competing methods).

Certain aspects of the present disclosure are directed to high-efficiency solar cell architectures. TAIC inherently allows for high efficiency solar cell architectures. The ability to create traditional p+/n/n+ or n+/p/p+ cells is the simplest implementation of TAIC. Aluminum has been shown to not over-compensate n-type a-Si:H with 10²⁰ cm⁻³ dopant concentrations. Highly doped a-Si:H films deposited with phosphine or diborane have been crystallized without changing type. This enables the technology to be used as both the emitter and the back surface field (BSF) of the same solar cell.

In certain embodiments, a cell architecture is similar to an HIT cell without the need for pristine, high vacuum a-Si:H deposition or expensive transparent-conductive ITO coatings. In one example, only the top-most a-Si:H is crystallized, leaving an ultra-thin layer in contact with the substrate.

Certain aspects of the present disclosure are directed to TAIC thin film silicon solar cell. Silicon based photovoltaics continue to dominate the market and may well do so for the foreseeable future. Wafer based technologies still benefit from decreasing costs and continued innovation. However, efficient and simple thin film technologies can capture a large part of the market by avoiding high materials cost.

In certain embodiments, polycrystalline silicon thin film solar modules can be produced using Plasma Enhanced Chemical Vapor Deposition (PECVD) of hydrogenated amorphous silicon (a-Si:H). In contrast, an SPC step can take 20 hours to achieve grain sizes 300 times smaller than what has been demonstrated by typical TAIC. The SPC process may also require temperatures of 550-700° C. and may have a mini-module conversion efficiency of only 9.8% [6]. In order to become competitive, however, full module conversion efficiencies>12% are required.

Certain aspects of the present disclosure are directed to controlling crystallization thickness and aluminum dopant control in TAIC. Achieving these two objectives will allow for thin film solar cells with a single a-Si:H deposition process and short processing times to be within reach. The technical objectives are critical to all applications of TAIC as well the general scientific understanding of this process.

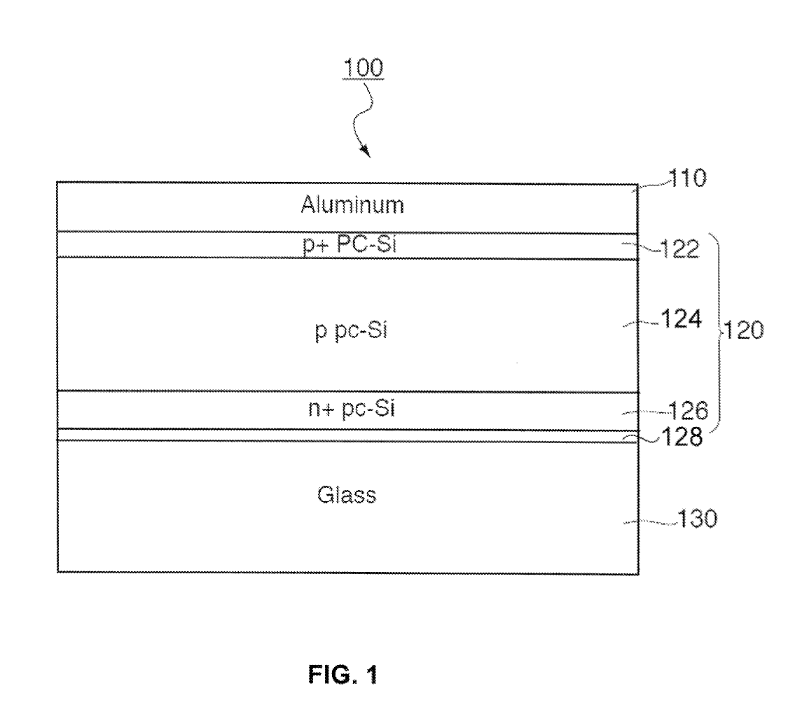

FIG. 1 schematically shows a cross-sectional view of a thin-film polycrystalline film structure, according to certain embodiments of the present disclosure. As shown, a polycrystalline film 120 with a plurality of polycrystalline layers 122, 124, 126 are formed or deposited on a substrate 130. A metal layer 110 is formed on the polycrystalline film 120.

More particularly, FIG. 1 schematically illustrates a cross-sectional view of a polysilicon solar cell 100, according to certain embodiments of the present disclosure. As shown, a polysilicon film 120 is formed on the glass substrate 130, and an aluminum layer 110 is formed on the amorphous silicon film 120. The amorphous silicon film 120 includes a p+ polycrystalline silicon (pc-Si) layer 122, a p-type pc-Si layer 124, and an n+ pc-Si layer 126, and is positioned between the aluminum layer 110 and the glass substrate 130. In certain embodiments, a layer of amorphous silicon carbide 128 is formed, as will be described below, in the polysilicon film 120. The layer of amorphous silicon carbide 128 can be positioned at various locations in the polysilicon film 120. For example, the layer of amorphous silicon carbide 128 can be positioned in the top portion, the middle portion, or the bottom portion of the polysilicon film 120. The layer of amorphous silicon carbide 128 can also be positioned in or near the pc-Si layer 122, the pc-Si layer 124, or the n+ pc-Si layer 126. In this specific example shown in FIG. 1, the layer of amorphous silicon carbide 128 is formed in contact with the glass substrate 130 and below the n+ pc-Si layer 126.

In certain embodiments, the light enters through the glass 130, passes through the n+ emitter layer 126, into the p-type base 110, from which charge carriers are reflected by the p+ back surface field (BSF) 122 and light is scattered back through the device by the reflective backside metal contact. A grid contact scheme is not shown in this illustration for simplicity, however between the glass 130 and the n+ emitter 126 would be antireflective coatings such as SiN or TCO and the glass 130 could be etched or treated otherwise to provide scattering at the surface of the solar cell as well.

In certain embodiments, polycrystalline emitters 126 for solar cells have the potential to dramatically increase the control with which solar cells are produced. Performance benefits have been both experimentally and theoretically explored due to both reduced back injection current, decreased emitter thickness, and the avoidance of a “dead layer.” Previous work was plagued by high carrier losses from defective grain boundaries which override LPCVD films. Also, high deposition temperatures eliminated useful defect-passivating hydrogen in these devices. With traditional cells, losses in the emitter mostly occur due to peak dopant concentration near the surface: increasing surface recombination while decreasing blue light response and collection probability from this region. To mitigate these problems, thinner emitters were employed which resulted in relatively high sheet resistances. However, open circuit voltages in excess of 650 mV were obtained on 0.1 Ωcm float zone wafers due to a minimized back injection current. Because of the relatively poor crystal quality of LPCVD films and grain sizes below 100 nm, short circuit current densities were limited by contributions from the substrate and values of 23.1 mA/cm2 were the highest obtained without an antireflection coating or texturing (light trapping schemes). Using the TAIC process, with large, well passivated grain boundaries we have obtained 28.6 mA/cm2 without an antireflection coating or much texturing on Cz wafers. This indicates a much higher quality material from TAIC compared to LPCVD.

In order for high-efficiency polysilicon emitter solar cells to be viable, high throughput, low temperature processes must be utilized which result in well passivated, large-grained films. TSIC can be used to create high efficiency polysilicon emitter solar cells.

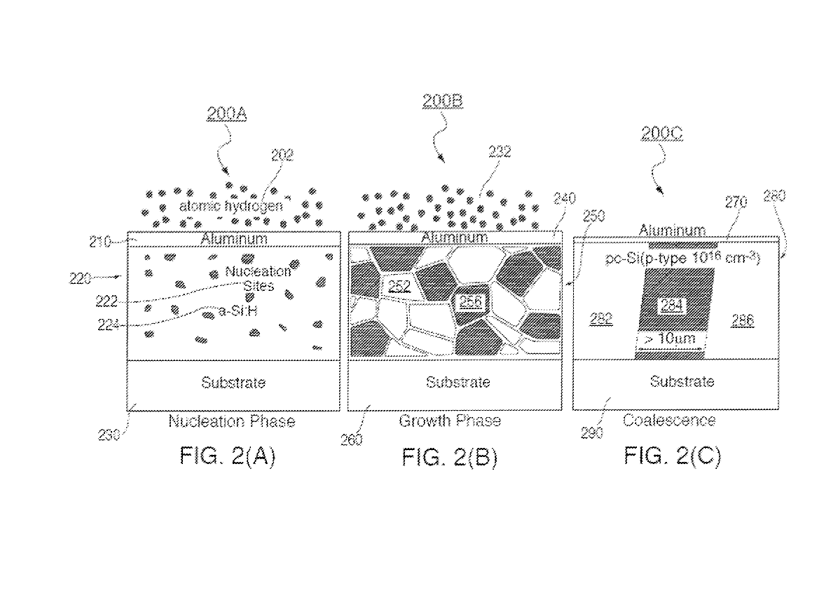

FIG. 2 is a cross-sectional view schematically illustrating three phases of metal-induced crystallization (MIC) for producing a doped polycrystalline film, according to certain embodiments, where (A) shows the nucleation phase 200A, (B) shows the growth phase 200B, and (C) shows the coalescence phase 200C. It should be noted that the region 220 in the nucleation phase shown in FIG. 2A corresponds to the region 250 in the growth phase shown in FIG. 2B and the region 280 in the coalescence phase shown in FIG. 2C. Likewise, the metal layer 210 shown in the nucleation phase of FIG. 2A corresponds to the metal layer 240 shown in the growth phase of FIG. 2B and the metal layer 270 shown in the coalescence phase of FIG. 2C. Further, the substrate 230 shown in the nucleation phase of FIG. 2A corresponds to the substrate 260 shown in the growth phase of FIG. 2B and the substrate 290 shown in the coalescence phase of FIG. 2C.

More particularly, FIG. 2 schematically shows hydrogen-assisted TAIC for producing a polycrystalline silicon layer for thin film photovoltaic cells. In hydrogen-assisted TAIC, atomic hydrogen 202 (FIG. 2A), 232 (FIG. 2B) enhances the diffusion of aluminum 210, 240, 270 to allow for even distribution of nucleation sites 222. In the nucleation phase 200A shown in FIG. 2A, a silicon film 220 is positioned between the aluminum layer 210 and a substrate 230. The silicon film 220 includes nucleation sites 222 and a-Si:H 224. As shown by the growth phase 200B in FIG. 2B together with the coalescence phase 200C in FIG. 2C, crystals 252 and 256 grow to meet one another and then coalesce to form single large grains 282, 284, and 286 with doping densities and crystallization depths controlled for the optimal properties needed by thin film silicon devices. Aluminum atoms form bonds with hydrogen and diffuse throughout the >2 μm a-Si:H depth quickly and evenly. By annealing in hydrogen, a three-dimensional crystal coalescence event is achieved for any desired thickness.

FIG. 3 schematically shows a cross-section of deposited layers and corresponding deposition methods and precursor gas environments for forming a polycrystalline film, collectively labeled 300, according to certain embodiments of the present disclosure. More particularly, FIG. 3 shows a process for depositing amorphous silicon film 320 with a thickness of about 2-10 μm on a glass substrate 330 in a disposition environment. In certain embodiments, the disposition environment can be filled with different precursor materials (e.g. in gaseous form) at different time points such that the precursor materials can react with the amorphous silicon film 320 and that the amorphous silicon film 320 can include layers of materials 322, 324, 326 that have different material or electrical characteristics. The amorphous silicon film 320 includes three layers: a p+ layer 322 formed by sputtering or PECVD in a environment that includes diborane; a n+ layer 326 formed by sputtering or PECVD in a environment that includes phosphine, and a layer 324 positioned between the first layer 322 and the second layer 326, formed in a environment that includes silane. In one embodiment, the three layers 322, 324, and 326 are formed in one continuous step of sputtering or PECVD. Further, a metal (e.g. aluminum) layer 310 is formed on the amorphous silicon film 320 by sputtering or thermal evaporation. In certain embodiments, the silicon film 320 is formed to have a thickness within a range from about 0.1 μm to about 40 μm. In certain embodiments, the silicon film 320 is formed by plasma-enhanced chemical vapor deposition at a pressure of about in a range from about 10⁻⁴ torr to about 10⁻⁶ torr, or preferably at about 10⁻⁶ torr. In certain embodiments, the metal layer 310 is formed to have a thickness in a range from about 5 nm to about 300 nm. In certain embodiments, the aluminum layer 310 is formed by sputtering at a pressure of about 10⁻⁸ torr.

In certain embodiments, hydrogenated amorphous silicon (a-Si:H) material is deposited on the glass 330 by sputtering or PECVD. During the process, hydrogenated amorphous silicon (a-Si:H) material initially is deposited in a deposition environment having a precursor gas such as phosphine to form a layer of n+a-Si:H 326. After a predetermined time or that the layer of n+a-Si:H 326 has reached a predetermined thickness, the precursor gas in the deposition environment is changed to a different precursor gas while the a-Si:H material is continuously being deposited. In certain embodiments, the precursor gas is changed to a precursor gas such as silane to form a layer of a-Si:H 324. After a predetermined time or that the layer of a-Si:H 324 has reached a predetermined thickness, the precursor gas in the deposition environment is changed to a different precursor gas while the a-Si:H material is continuously being deposited. In certain embodiments, the precursor gas is changed to a precursor gas such as diborane to form a layer of P+ a-Si:H 322. After a predetermined time or that the layer of P+ a-Si:H 322 has reached a predetermined thickness, the process stops depositing the a-Si:H material. In certain embodiments, the process then continues with depositing a layer of aluminum 310 on the amorphous silicon film 320 by sputtering or thermal evaporation.

In certain embodiments, metal atoms diffuse through and initiate crystallization of a-Si:H films at temperatures well below the eutectic temperatures. FIG. 2 illustrates an example where aluminum is used. Aluminum is a low level acceptor impurity and it is the third most abundant element in the earth's crust. The eutectic temperature of aluminum and silicon is 577° C. TAIC can be used to crystallize a-Si:H at temperatures as low as 100° C. In performing TAIC, a thin layer of aluminum is deposited onto the surface of the a-Si:H layer, which has a native oxide layer that limits the diffusion of aluminum. This native oxide layer represents a relaxed manufacturing constraint because exposure to air is non-problematic. It limits the diffusion of the aluminum causing fewer initial nucleation sites. The result has been shown to produce very large grain polysilicon.

The a-Si:H layers can be fully crystallized in less than an hour. Lower annealing temperatures can result in larger grain sizes, and also that thinner aluminum layers actually increase grain sizes. Both of these reductions from a manufacturing standpoint are quite appealing. For instance, to form the emitter layers of 4″ solar cells using TAIC, a manufacturer only needs the equivalent of one soda can tab, and instead of requiring many hours of temperatures in excess of 850° C. for thermal diffusion, a manufacturer needs less than 300° C. for less than an hour.

Certain aspects of the present disclosure are directed to crystallization depth control. Grain sizes throughout the active layer of thin film polysilicon cells should be greater than 10 μm because the defects at grain boundaries act as trapping, scattering, and recombination centers. Conventionally, large grain thin film solar cells have been achieved by starting with a large grain seed layer. The seed layer can be created either by re-annealing with lasers or with variants of MIC. MIC specifically with aluminum and nickel has been shown to create grains in excess of 90 μm for a-Si:H thicknesses of less than 200 nm, yielding high grain diameter/layer thickness aspect ratios. With effective light trapping techniques, the thickness of a thin film crystalline solar cell needs to be 2 μm. Therefore the crystallization depth of TAIC should be controlled to achieve a process requiring the lowest processing time and temperature and to yield large grain sizes, for applications in fields of technology such as the creation of thin film polycrystalline solar cells. Certain embodiments of the present disclosure can provides full crystallization of thick (>2 μm) amorphous silicon films using TAIC.

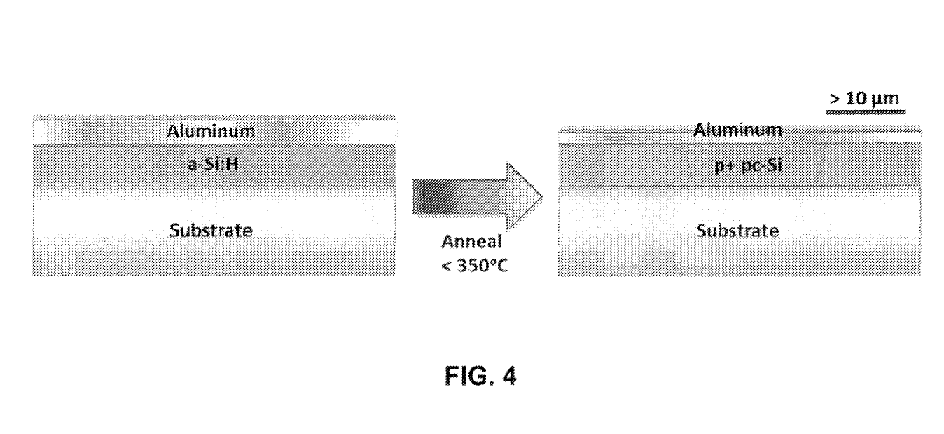

In certain embodiments, the structures formed as shown in FIG. 3 are annealed in an atomic hydrogen environment as illustrated in FIGS. 2 and 4. In certain embodiments, the amorphous silicon film 320 is at least partially crystallized during the annealing process. A lighter doped (10¹⁶ cm⁻³) p-type base layer 110 is created for a thin film solar cell that only requires a single step TAIC process. Since a hydrogenation step only affects the p+ doped layer 122 and not the n+ emitter layer 126, doping density is tuned during the annealing step through controlling the temperature as well as the ambient hydrogen content. Hydrogen passivation of grain boundaries in multicrystalline solar cells has been found to increase overall conversion efficiencies. Hydrogen passivation of intragrain defects and grain boundaries is necessary to optimize electrical characteristics of thin film polycrystalline solar cells, however this hydrogenation step generally occurs after deposition. By hydrogenating while annealing, an extra manufacturing step can be eliminated.

Atomic hydrogen increases the diffusivity of aluminum into a-Si:H, thereby enhancing the crystallization process of TAIC. Hydrogen has also been found to enhance the diffusivity of boron by a factor of two into SiO₂. Aluminum atoms form bonds with hydrogen and diffuse throughout the >2 μm a-Si:H quickly and evenly. By annealing in hydrogen, a three-dimensional crystal coalescence event is achievable for any desired thickness. In production, it is essential to maintain optimal grain sizes (>10 μm) while at the same time controlling the doping density and thickness of crystallization.

One challenge for realizing the TAIC technology is limited open circuit voltage (Voc) most likely due to interface crystallization defects or aluminum contamination. In certain embodiments, one approach is inserting a crystallization-stop by altering the amorphous silicon such that the portion at the interface has a higher crystallization temperature than the remainder of the film.

Certain aspects of the present disclosure are directed to a process that can selectively crystallize multiple layers of hydrogenated amorphous silicon such as those illustrated in FIG. 3. In certain embodiments, a layer of amorphous material in film 320 is engineered to have a higher crystallization temperature than the surrounding layers. For example, in a deposition process that is similar the process discussed above, the location and thickness of the layer 128 having higher crystallization temperature can be controlled. For example, during the process of depositing amorphous material on the substrate 330, after a predetermined time or that the amorphous material has reached a predetermined thickness, a material that can alter the crystallization characteristics, such as the crystallization temperature of the amorphous material, can be introduced in the deposition environment. Then, after another predetermined time or that the amorphous material has reached another predetermined thickness, the material altering the crystallization characteristics can be removed from the deposition environment. This enables crystallization of some layers and non-crystallization of other layers. The crystallization-stop layer can be positioned at virus location of the film 320. In certain embodiments, the crystallization-stop layer is formed to be in contact with the substrate.

In certain embodiments, the annealing temperature is in the range of between about 100° C. to about 1000° C. In various embodiments, the annealing temperature can be in the range from about 200° C. to about 900° C., from about 300° C. to about 800° C., from about 400° C. to about 700° C., or from about 500° C. to about 600° C. In certain embodiments, the temperature range from about 100° C. to about 1000° C. can have various temperature points that evenly divide the temperature range by intervals of 5° C. (e.g. a first temperature point at 105° C. and a second temperature point at 110° C., etc.). The annealing temperature can be between about any two of the temperature points.

In certain embodiments utilizing a TAIC process, methane gas can be introduced in the deposition environment during the amorphous silicon deposition, e.g. at the beginning of the deposition, to result in a layer of amorphous silicon carbide in the amorphous silicon film 320. Amorphous silicon carbide has a higher crystallization temperature than amorphous silicon and would remain amorphous while the non-silicon carbide layers crystallize during annealing. In certain embodiments, the methane gas is introduced in the deposition environment before, while, or after the phosphine gas is introduced in the deposition environment. In certain embodiments, the methane gas is introduced in the deposition environment before, while, or after the silane gas is introduced in the deposition environment. In certain embodiments, the methane gas is introduced in the deposition environment before, while, or after the diborane gas is introduced in the deposition environment.

In order to enable the heterojunction architecture, the development of crystallization-stop technology will be necessary. Due to the high resistivity of a-Si:H films, the layer thickness must be minimized and must provide excellent surface passivation to the crystalline silicon substrate as well as the overlying TAIC polysilicon layer. In certain embodiments, methane is introduced as a precursor gas to grow less than about 1 μm, or preferably less than about 20 nm, a-SiC:H. Carbon impurities drastically raise the crystallization temperature of the amorphous material. This layer would remain amorphous and intact, providing ideal junction conditions for a low-temperature heterojunction solar cell.

Certain aspects of the present disclosure are directed to doping amorphous silicon without crystallization. Under certain circumstances, TAIC can dope amorphous silicon without crystallizing it. In certain embodiments, TAIC can dope amorphous silicon without crystallizing it with stable open circuit voltages of >620 mV (one sun at room temperature).

Certain embodiments of the present disclosure can be applied to plasmonics. TAIC itself is particularly amenable to plasmonic integration, since structures can be included anywhere from the junction itself to the surface of the emitter. It may also be possible, since aluminum has been shown to be a candidate plasmonic material, that some plasmonic effects are inherently available in the TAIC process discussed here.

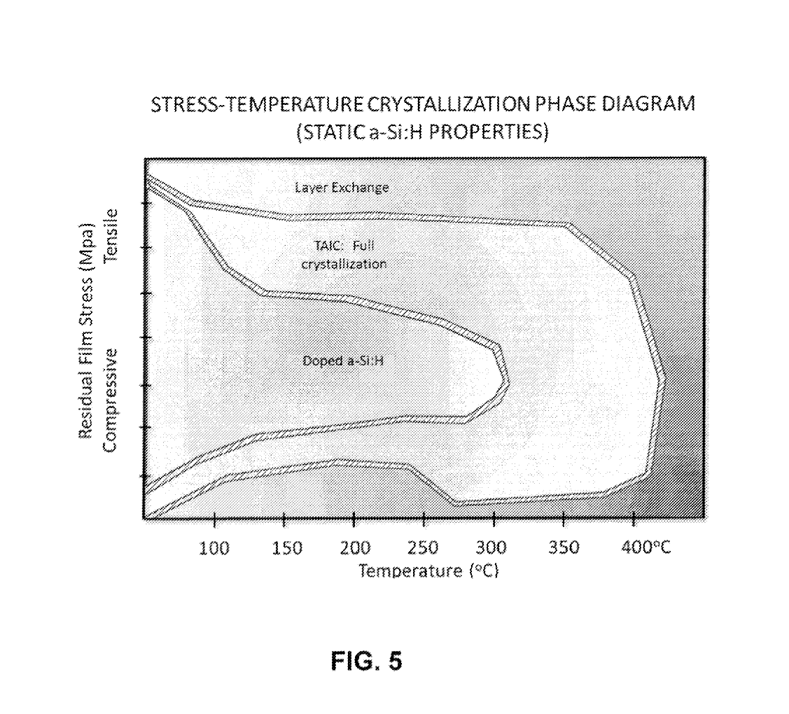

There are three main, interrelated factors which control the spectrum of crystallization possible with TAIC. This spectrum ranges from simply doping amorphous silicon without crystallization to full crystallization with texturing (sparse layer exchange). Even though TAIC is capable of full layer exchange, this configuration has limited applicability to the cell architectures described previously. The three main factors that must be understood in order to control TAIC are stress, a-Si:H hydrogen content, and annealing temperature. These factors are easily measured and can be thought of as constituting a sort of crystallization-phase parameter space. Given the same starting factor, the other two factors can result in any and all crystallization modes already mentioned. FIG. 5 is a stress-temperature crystallization phase diagram. Each of these parameters is more complex than has been described here. For example, identified here are five measureable, controllable factors ultimately dictating effective stress, five dictating the microstructure of a-Si:H, and three factors affecting the annealing process. Some of these are more robust than others in terms of their overall effect on the final crystalline film quality, but each is individually well understood and easily linked to their respective main factors.

1) Stress: Stress on TAIC has a noticeable effect on crystallization. In certain circumstances, a complete understanding of stress requires control of the following five sub-factors contributing to overall stress:
Substrate rigidity;
Residual stress from a-Si:H deposition;
Residual stress from aluminum deposition;
Coefficient of thermal expansion mismatch between aluminum/a-Si:H/substrate; and

Microstructural changes including crystallization kinetics.

These sub-factors can be measured via laser profilometry of the surface of substrates before and after thin film deposition. Stress is a dynamic factor that changes during each step of the process.

2) Hydrogen: The amount and type of bonded hydrogen can drastically influence crystallization of both sputtered a-Si:H and PECVD films. High quality, low deposition rate a-Si:H unders certain circumstances is not necessarily the best precursor for device-quality TAIC polysilicon. The following sub-factors control the life of hydrogen throughout TAIC:
Deposition temperature;
Deposition pressure;
Deposition precursor gases;
Annealing temperature; and
Crystallization kinetics.

3) Annealing: Factors important to annealing are temperature profile, annealing environment (vacuum, gas, etc.) as well as type (IR lamp irradiation, conductive heating, etc.). IR lamps can be used for controlled as well as rapid thermal annealing. 3D heat transfer modeling software can be used to document heating profiles.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims

1. A method, comprising:
providing a first precursor material in a deposition environment;
providing a second precursor material in the deposition environment;
depositing, in the deposition environment an amorphous semiconductor material on a substrate to form a semiconductor film on the substrate,
wherein the first precursor material provided in the deposition environment is configured such that the semiconductor film, as formed on the substrate, includes a first layer having a first material characteristic, and
wherein the second precursor material provided in the deposition environment is a crystallization-stop precursor material configured such that the semiconductor film, as formed on the substrate, includes a crystallization-stop layer below the first layer and having a crystallization characteristic that is different from a crystallization characteristic of the first layer;
depositing a metal film on the semiconductor film; and
annealing the semiconductor film and the metal film at a predetermined annealing temperature for a predetermined period of time such that the first layer is at least partially crystallized and the crystallization-stop layer is at least partially amorphous.

2. The method of claim 1, further comprising providing a third precursor material in the deposition environment, the third precursor material having a material characteristic such that the semiconductor film, as formed on the substrate, includes a second layer below the first layer and below the crystallization-stop layer and having a second material characteristic that is different from the first material characteristic, wherein the crystallization characteristic of the crystallization-stop layer is different from a crystallization characteristic of the second layer, and wherein annealing the semiconductor film comprises annealing the semiconductor film such that the second layer is at least partially crystallized.

3. The method of claim 2, further comprising providing a third precursor material in the deposition environment, the third precursor material configured such that the semiconductor film, as formed on the substrate, includes a third layer having a third material characteristic that is different from the first layer material characteristic and the third layer material characteristic, and wherein annealing the semiconductor film comprises annealing the semiconductor film such that the third layer is at least partially crystallized.

4. The method of claim 3, wherein third precursor material is provided subsequent to providing the third precursor material and the third precursor material is provided subsequent to providing the first precursor material.

5. The method of claim 4, wherein the second precursor material is provided prior to providing the first precursor material.

6. (canceled)

7. The method of claim 3, wherein the amorphous semiconductor material is a hydrogenated amorphous silicon material.

8. The method of claim 7, wherein the first, second, third, and crystallization-stop precursor materials are in gaseous forms.

9. The method of claim 8, wherein the first, second, and third layers are entirely crystallized and the crystallization-stop layer is entirely amorphous.

10. The method of claim 8, wherein the first precursor material is phosphine and the first layer contains an n+ hydrogenated amorphous silicon material.

11. The method of claim 8, wherein the second precursor material is silane and the second layer contains a hydrogenated amorphous silicon material.

12. The method of claim 8, wherein the third precursor material is diborane and the third layer contains a p+ hydrogenated amorphous silicon material.

13. The method of claim 8, wherein the crystallization characteristic corresponds to a crystallization temperature.

14. The method of claim 13, wherein the crystallization-stop precursor material is methane and the crystallization-stop layer contains amorphous silicon carbide.

15. The method of claim 14, wherein the crystallization-stop layer has a thickness less than about 1 μm.

16. The method of claim 14, wherein the crystallization-stop layer has a thickness less than about 20 nm.

17. The method of claim 13, wherein the semiconductor film and metal film are annealed in an atomic hydrogen environment.

18. The method of claim 13, wherein the annealing temperature is above or equal to a first temperature at which the first, second, and third layers start crystallization in the annealing process and is below a second temperature at which the crystallization-stop layer starts crystallization in the annealing process.

19. The method of claim 18, wherein the annealing temperature is within a range from about 100° C. to about 1000° C.

20. The method of claim 19, wherein the crystallization-stop layer comprises a layer of amorphous silicon carbide having a thickness less than 1 μm.

21. The method of claim 8, wherein the metal film is an aluminum film.

22. The method of claim 8, wherein the substrate is a glass substrate.

23. The method of claim 8, wherein the semiconductor film is formed to have a thickness within a range from about 0.1 μm to about 40 μm.

24. The method of claim 8, wherein the semiconductor film is formed by sputtering or chemical vapor deposition.

25. The method of claim 8, wherein the semiconductor film is formed by plasma-enhanced chemical vapor deposition at a pressure in a range from about 10⁻⁴ torr to about 10⁻⁶ ton.

26. The method of claim 8, wherein the metal film is formed to have a thickness in a range from about 5 nm to about 300 nm.

27. The method of claim 8, wherein the metal film is formed by sputtering or thermal evaporation.

28. The method of claim 8, wherein the metal film is formed by sputtering at a pressure of about 10⁻⁸ ton.

29. The method of claim 8, wherein the predetermined period of time is within a range from about 15 minutes to about 20 hours.

30. The method of claim 3, further comprising at least one of:
controlling rigidity of the substrate;
controlling residual stress from the semiconductor film;
controlling residual stress from the metal film;
controlling coefficient of thermal expansion mismatch between the metal film, the semiconductor film, and the substrate;
and controlling micro-structural changes associated with the semiconductor film, including crystallization kinetics.

31. The method of claim 3, further comprising at least one of:
controlling a deposition temperature;
controlling a deposition pressure;
controlling a deposition precursor gas;
controlling the annealing temperature; and
controlling crystallization kinetics of the semiconductor film.

32. The method of claim 3, further comprising at least one of:
controlling an annealing temperature profile;
controlling an annealing environment; and
controlling an annealing type.

33. A polycrystalline silicon film structure formed by the method of claim 1.

34. A semiconductor film structure, comprising:
a substrate;
a semiconductor film formed on the substrate, wherein the semiconductor film is a layered structure including a first layer having a first material characteristic and being at least partially crystallized, and a crystallization-stop layer formed above the substrate and below the first layer and being at least partially amorphous; and
a metal film formed on the semiconductor film.

35. The semiconductor film structure of claim 34, wherein the semiconductor film further comprises a second layer having a second material characteristic different from the first material characteristic and formed below the first layer and below the crystallization-stop layer, the second layer being at least partially crystallized.

36. The semiconductor film structure of claim 35, wherein the semiconductor film further comprises a third layer having a third material characteristic different from the first and second material characteristics.

37. The semiconductor film structure of claim 34, wherein the semiconductor film is a silicon film.

38. The semiconductor film structure of claim 37, wherein the first layer contains an n+ poly crystalline silicon material.

39. The semiconductor film structure of claim 37, wherein the second layer contains a p type polycrystalline silicon material.

40. The semiconductor film structure of claim 37, wherein the third layer contains a p+ polycrystalline silicon material.

41. The semiconductor film structure of claim 37, wherein the crystallization-stop layer contains amorphous silicon carbide.

42. A layered structure, comprising:
a silicon film including a first polycrystalline silicon layer having a first material characteristic;
a second polycrystalline silicon layer having a second material characteristic and formed below the first layer;
a third polycrystalline silicon layer having a third material characteristic wherein the first, second, and third material characteristics are different from each other; and
a crystallization-stop layer formed in the silicon film, above the second layer and below the first layer, having a crystallization characteristic different from crystallization characteristics of the first, second and third layers, wherein the first, second and third layers are at least partially crystallized and the crystallization-stop layer is at least partially amorphous.

43. The layered structure of claim 42, wherein the first layer contains an n+ polycrystalline silicon material.

44. The layered structure of claim 42, wherein the second layer contains a p type polycrystalline silicon material.

45. The layered structure of claim 42, wherein the third layer contains a p+ polycrystalline silicon material.

46. The layered structure of claim 42, wherein the crystallization-stop layer contains amorphous silicon carbide.
